(19) United States
(12) Patent Application Publication
(10) Pub. No.: US 2026/0198005 A1
(43) Pub. Date: Jul. 9, 2026

(54) MEMORY DEVICE

(71) Applicant: MACRONIX International Co., Ltd., Hsinchu (TW)

(72) Inventors: Chen-Yu Cheng, Hsinchu City (TW); Tzung-Ting Han, Hsinchu City (TW)

(73) Assignee: MACRONIX International Co., Ltd., Hsinchu (TW)

(21) Appl. No.: 19/013,965

(22) Filed: Jan. 8, 2025

(51) Int. Cl. H10B 43/27; H10B 43/10; H10B 43/35

(52) U.S. Cl. CPC H10B 43/27; H10B 43/10; H10B 43/35

(57) ABSTRACT

A memory device contains a first memory array configuration, a second memory array configuration, and a central connection configuration located between the first and the second memory array configuration. The memory device includes a stack structure having a plurality of insulating layers and a plurality of conductive layers stacked alternately in above configurations. A plurality of ground select line structures is included in the plurality of conductive layers in a lower portion of the stack structure. The stack structure in the central connection configuration further includes a first connect structure, a second connect structure, and a bridge structure. The first and the second connect structures are respectively connected with the stack structure of the first and the second memory array configuration, wherein the second connect structure and the first connect structure are arranged in a staggered pattern. The bridge structure connects the first and the second connect structures.

### BACKGROUND

### Technical Field

The present disclosure relates to a memory device.

### Description of Related Art

Non-volatile memory devices, by virtue of their capacity to retain stored data even in the absence of power, have consequently emerged as a widely adopted form of memory device in personal computers and diverse electronic devices.

The current industry commonly employs flash memory arrays, including NOR flash memory and NAND flash memory. Due to the structure of NAND flash memory, wherein memory cells are connected in series, it exhibits superior integration density and area utilization compared to NOR flash memory. Consequently, NAND flash memory has been widely implemented in various electronic products. Furthermore, to further enhance the integration density of memory devices, a three-dimensional NAND flash memory has been developed. Nevertheless, numerous challenges associated with three-dimensional NAND flash memory persist.

### SUMMARY

The present disclosure provides a memory device that reduces word line (WL) RC delay in memory array structures.

In an embodiment of the present disclosure, a memory device includes a first memory array configuration, a second memory array configuration, and a central connection configuration located between the first and second memory array configurations. The memory device includes a stack structure. The stack structure includes a plurality of insulating layers and a plurality of conductive layers alternately stacked in the first memory array configuration, the second memory array configuration, and the central connection configuration, wherein the ground select line structures (GSLs) are included in the conductive layers in the lower portion of the stack structure in the first memory array configuration, the second memory array configuration, and the central connection configuration. The stack structure in the central connection configuration further includes a first connect structure, a second connect structure, and a bridge structure. The first connect structure is connected to the stack structure of the first memory array configuration, and the second connect structure is connected to the stack structure of the second memory array configuration, wherein the second connect structure and the first connect structure are arranged in a staggered pattern. The bridge structure connects the first connect structure and the second connect structure.

In an embodiment of the present disclosure, a memory device includes a plurality of zones. Each of the zones is disposed between a first slit and a second slit opposite to each other for separating from adjacent zones of the plurality of zones. The memory device includes a stack structure. The stack structure includes a plurality of insulating layers and a plurality of conductive layers alternately stacked in each of the zones, wherein the stack structure at a first end of the zone includes a first memory array configuration, the stack structure at a second end of the zone includes a second memory array configuration, and a plurality of ground select line structures are disposed in the lower portion of the stack structure. The ground select line structure extends from the first end of the zone to the second end of the zone. Each of the zones further includes a central connection configuration, disposed between the first memory array configuration and the second memory array configuration. The stack structure in the central connection configuration includes a first connect structure, a second connect structure, and a bridge structure. The first connect structure is disposed along the first slit to connect the first memory array configuration. The second connect structure is disposed along the second slit to connect the second memory array configuration. The bridge structure connects the first connect structure and the second connect structure.

Based on the foregoing, the central connection configuration in the embodiments of the present disclosure employs a bridge structure to connect two connect structures (such as WL structure) that are respectively connected to the first and second memory array configurations. Consequently, this configuration enables the connection of WLs of the first and second memory array configurations at both ends through conductive paths of equal distance, thereby reducing WL RC delay in the memory array structure.

### BRIEF DESCRIPTION OF THE DRAWINGS

FIG. 1 is a perspective view of a memory device according to an embodiment of the present disclosure.

FIG. 2 is a top view of a memory device according to an embodiment of the present disclosure.

FIG. 3 is a cross-sectional view along line A-A′ of FIG. 2.

FIG. 4 is a cross-sectional view along line B-B′ of FIG. 2.

FIG. 5 is a cross-sectional view along line C-C′ of FIG. 2.

FIG. 6 is a cross-sectional view of a memory device according to an embodiment of the present disclosure.

### DESCRIPTION OF THE EMBODIMENTS

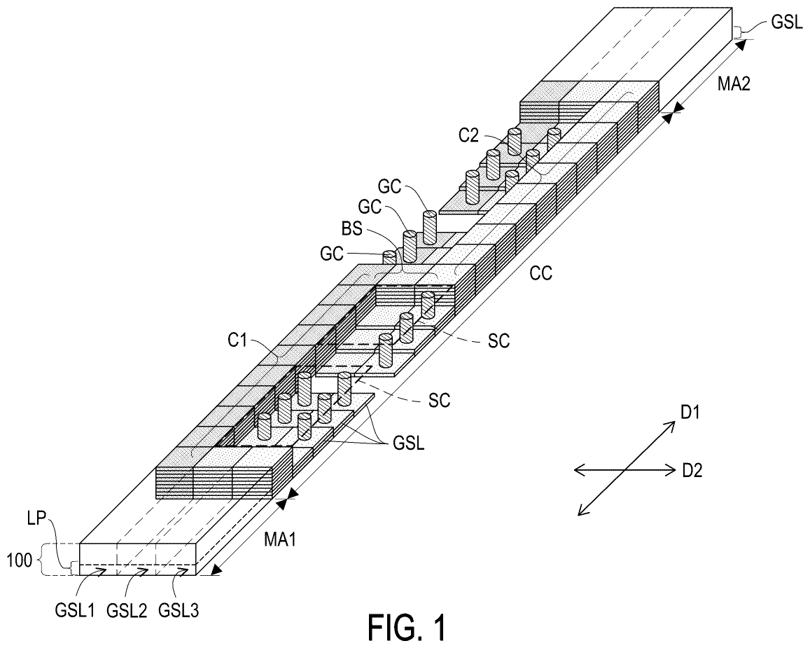

FIG. 1 is a perspective view of a memory device according to an embodiment of the present disclosure.

Referring to FIG. 1, the memory device includes a first memory array configuration MA1, a second memory array configuration MA2, and a central connection configuration CC located between the first memory array configuration MA1 and the second memory array configuration MA2. The memory device is constituted by a stack structure 100, the stack structure 100 includes a plurality of insulating layers and a plurality of conductive layers alternately stacked in the first memory array configuration MA1, the second memory array configuration MA2, and the central connection configuration CC. Detailed structures of the stack structure 100, the first memory array configuration MA1, and the second memory array configuration MA2 will be described below. There are ground select line structures GSL (i.e., conductive layers) in the lower portion LP of the stack structure 100 within the first memory array configuration MA1, the second memory array configuration MA2, and the central connection configuration CC, and FIG. 1 only shows the conductive layers in the stack structure 100, while the insulating layers (not shown) in the stack structure 100 are interposed between the conductive layers. The stack structure 100 of the central connection configuration CC further includes a first connect structure C1, a second connect structure C2, and a bridge structure BS. The first connect structure C1 is connected to the stack structure 100 of the first memory array configuration MA1, and the second connect structure C2 is connected to the stack structure 100 of the second memory array configuration MA2, wherein the second connect structure C2 and the first connect structure C1 are arranged in a staggered pattern. The bridge structure BS connects the first connect structure C1 and the second connect structure C2.

In FIG. 1, the first connect structure C1 extends in the first direction D1 and continuously extends from the first memory array configuration MA1 to the bridge structure BS; the second connect structure C2 similarly extends in the first direction D1 and continuously extends from the second memory array configuration MA2 to the bridge structure BS. Correspondingly, the bridge structure BS extends in the second direction D2, and the second direction D2 is different from the first direction D1, for instance, the second direction D2 is perpendicular to the first direction D1 or there is an angle between the second direction D2 and the first direction D1. The memory device includes a plurality of staircase parts, for example, there are staircase parts SC extending in the first direction D1 in each of the ground select line structures GSL within the central connection configuration CC. The staircase parts SC are separated from each other in the first direction D1.

The memory device of this embodiment further includes a plurality of ground select line contacts GC, landing on staircase parts SC, so as to electrically connect to the respective ground select line structures GSL. For instance, the ground select line structures GSL in this embodiment include a first ground select line structure GSL1, a second ground select line structure GSL2, and a third ground select line structure GSL3. The second ground select line structure GSL2 is disposed between the first ground select line structure GSL1 and the third ground select line structure GSL3. The first ground select line structure GSL1, the second ground select line structure GSL2, and the third ground select line structure GSL3 may be isolated from each other by bottom walls called as ground select line cuts (not shown). FIG. 1 illustrates four staircase parts SC, respectively located in the first ground select line structure GSL1 at one end of the first connect structure C1 relative to the first memory array configuration MA1, in the third ground select line structure GSL3 at one end of the second connect structure C2 relative to the second memory array configuration MA2, in the second ground select line structure GSL2 and the third ground select line structure GSL3 adjacent to the first memory array configuration MA1, and in the second ground select line structure GSL2 and the first ground select line structure GSL1 adjacent to the second memory array configuration MA2. Consequently, the ground select line contacts GC may be coupled to all ground select line structures GSL of the first memory array configuration MA1 and the second memory array configuration MA2 through the respective staircase parts SC.

In some embodiments, the first connect structure C1 is disposed directly above the first ground select line structure GSL1 and is connected to a plurality of conductive layers (such as word lines (WL)) disposed above the lower portion LP of the stack structure 100 in the first memory array configuration MA1. In some embodiments, the second connect structure C2 is disposed directly above the third ground select line structure GSL3 and is connected to a plurality of conductive layers disposed above the lower portion LP of the stack structure 100 in the second memory array configuration MA2. In some embodiments, the bridge structure BS is disposed directly above the second ground select line structure GSL2 and is connected to both the first connect structure C1 and the second connect structure C2. Since the first connect structure C1 and the second connect structure C2 are connected to the first memory array configuration MA1 and the second memory array configuration MA2 at approximately equal distances, the WL RC delay in the first memory array configuration MA1 and the second memory array configuration MA2 may be reduced.

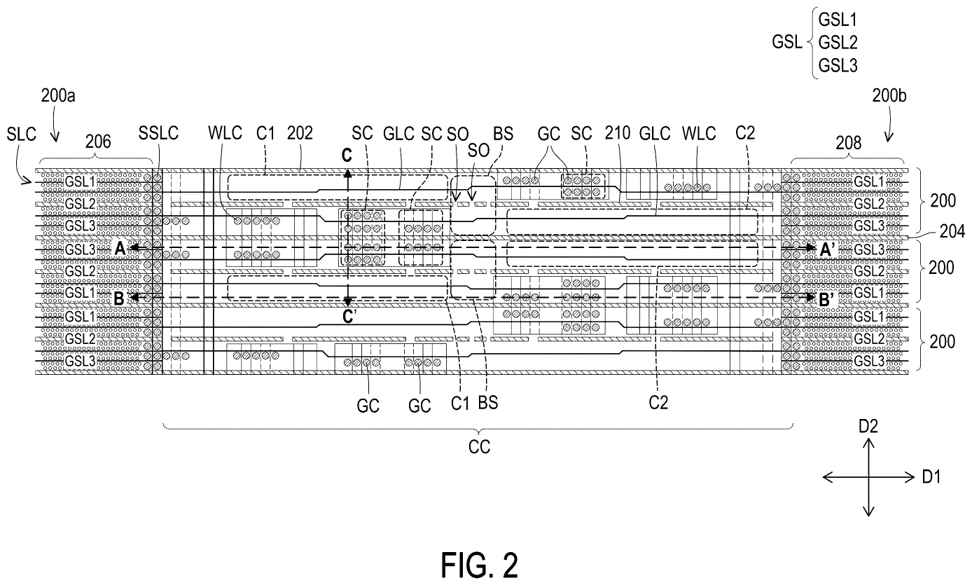

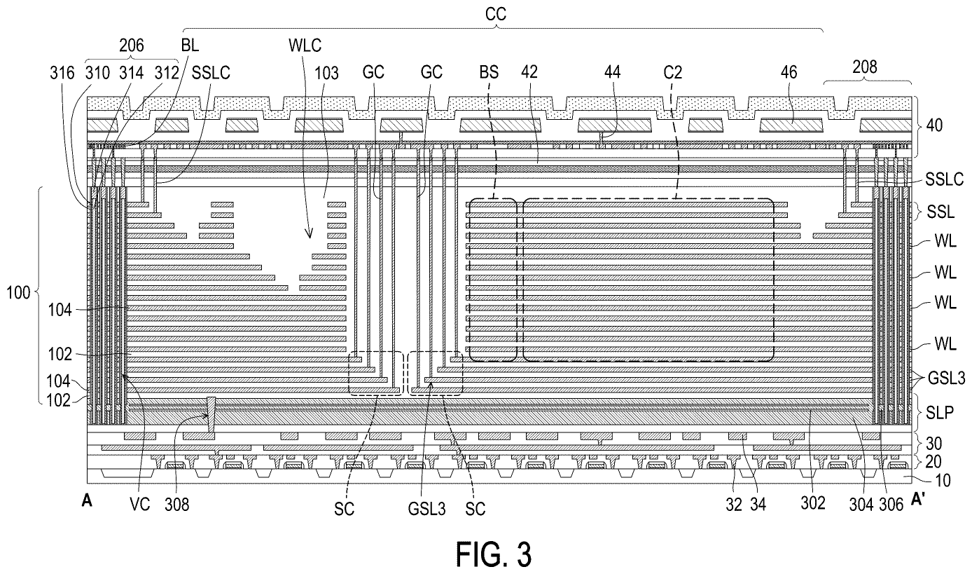

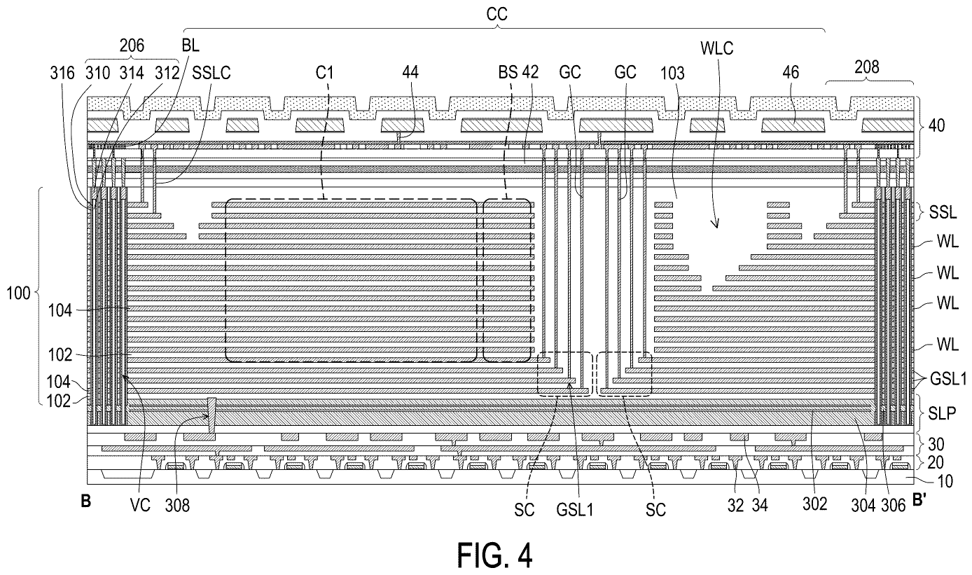

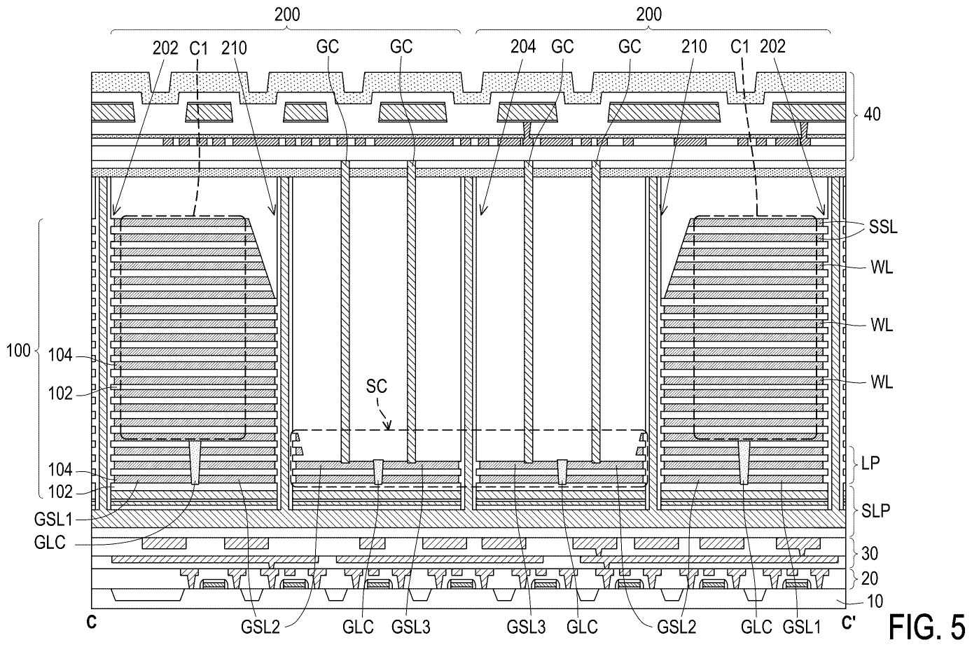

FIG. 2 is a top view of a memory device according to an embodiment of the present disclosure. FIG. 3 is a cross-sectional view along line A-A′ of FIG. 2. FIG. 4 is a cross-sectional view along line B-B′ of FIG. 2. FIG. 5 is a cross-sectional view along line C-C′ of FIG. 2.

Referring to FIG. 2 and FIG. 3, the memory device includes a plurality of zones 200, each of the zones 200 is disposed between a first slit 202 and a second slit 204 opposite to each other for separating adjacent zones 200 of the plurality of the zones 200. FIG. 2 illustrates three zones 200, wherein the configuration of adjacent zones 200 exhibits a mirror arrangement, thereby enabling adjacent zones 200 to share the same second slit 204 (or first slit 202), and so forth. Moreover, the number of zones 200 may be increased or decreased as required, and is not limited to the illustrated configuration. The memory device includes a stack structure 100. The stack structure 100 includes a plurality of insulating layers 102 and a plurality of conductive layers 104 alternately stacked within each of the zones 200, wherein the stack structure 100 at a first end 200a of the zone 200 includes a first memory array configuration 206, and the stack structure 100 at a second end 200b of the zone 200 includes a second memory array configuration 208.

In FIG. 3, there are devices under the stack structure 100, indicating that the memory device of this embodiment belongs to a CUA (CMOS-Under-Array) structure; however, the present disclosure is not limited thereto. In some embodiments, a device layer 20 is formed on the substrate 10. The device layer 20 may include active devices or passive devices. The active devices may include, for example, transistors, diodes, and the like. The passive devices may include, for example, capacitors, inductors, and the like. Transistors may be N-type Metal-Oxide-Semiconductor (NMOS) transistors, P-type Metal-Oxide-Semiconductor (PMOS) transistors, or Complementary Metal-Oxide-Semiconductor (CMOS) devices. A metal interconnect structure 30 is situated above the device layer 20. The metal interconnect structure 30 may include a multi-layered dielectric layer 32 and a metal interconnect 34 (including plugs, conductive lines, etc.) formed within the multi-layered dielectric layer 32. The metal interconnect 34 may be connected to the device layer 20. A source line plate SLP is disposed above the metal interconnect structure 30. The SLP may include a plurality of insulating layers 302 and a plurality of conductive layers 304 and 306. In an embodiment, the material of the insulating layer 302 includes silicon oxide. The material of the conductive layers 304 and 306 includes doped polysilicon. The number of insulating layer 302 and the number of the conductive layers 304 and 306 are not limited to what is shown in the figure. Furthermore, a conductive pillar 308 may be present within the source line plate SLP. The conductive pillar 308 has a low resistance. In an embodiment, the conductive layer 304 is composed of doped polysilicon, while the conductive pillar 308 is composed of metal, such as tungsten, titanium nitride, tantalum, or a combination thereof. The resistance of the conductive pillar 308 is lower than that of the conductive layer 304 within the source line plate SLP. The conductive pillar 308 may be electrically connected to the substrate 10 through the metal interconnect 34 in the metal interconnect structure 30, thereby providing a ground connection. Consequently, the conductive pillar 308 may serve as a discharge path.

Referring again to FIG. 3, a stack structure 100 is formed on the source line plate SLP. The number of insulating layers 102 and conductive layers 104 in the stack structure 100 is not limited to that shown in the figure. In an embodiment, the material of the insulating layer 102 includes silicon oxide. The conductive layer 104, for example, includes a barrier layer and a metal layer. In an embodiment, the material of the barrier layer includes titanium (Ti), titanium nitride (TiN), tantalum (Ta), tantalum nitride (TaN), or a combination thereof, while the material of the metal layer includes tungsten (W). In some embodiments, the positions of the individual conductive layers 104 are originally polysilicon, which are transformed into metal material layers through a gate replacement process. The first memory array and the second memory array are formed in the middle portion of the stack structure 100 of the first memory array configuration 206 and the second memory array configuration 208. Each of the first memory arrays and the second memory arrays includes a plurality of word lines (WL), vertical channel pillars composed of a channel layer 310, an insulating pillar 312, and a conductive plug 314, and a charge storage structure 316 surrounding each vertical channel pillar, thus forming a plurality of memory cells arranged in three dimensions. The word line WL is the conductive layer 104 in the middle portion of the stack structure 100. In some embodiments, the material of the channel layer 310 includes polysilicon, the material of the conductive plug 314 includes polysilicon, and the material of the insulating pillar 312 includes silicon oxide, but is not limited thereto. The charge storage structure 316 vertically surrounds the outer surface of the vertical channel pillar. In some embodiments, the charge storage structure 316 is an oxide/nitride/oxide (ONO) composite layer, but is not limited thereto. As for the upper portion of the stack structure 100, there are string selection lines SSL. The string selection lines SSL are the conductive layers 104 in the upper portion of the stack structure 100. The memory device further includes a metal interconnect structure 40, disposed above the stack structure 100. The metal interconnect structure 40 may include a multi-layered dielectric layer 42, a plurality of plugs 44, and a plurality of conductive lines 46. The dielectric layer 42 isolates the individual conductive lines 46 from the underlying first memory array configuration 206 and the underlying second memory array configuration 208. The conductive lines 46 may be connected each other by the plugs 44, and the conductive lines 46 may be coupled to the ground select line contacts GC, the string selection line contacts SSLC, and the word line contacts WLC, respectively. Although FIG. 3 does not show the word line contact WLC, their specific locations may be obtained from the top view (FIG. 2), namely the positions indicated by arrows in FIG. 3. In other words, the middle and upper portions of the stack structure 100 further have a plurality of staircase parts, providing areas for the landing of the word line contacts WLC or the string selection line contacts SSLC. The conductive lines 46 coupled to the conductive plugs 314 of the vertical channel pillars may serve as bit lines (or local bit lines) BL.

Continuing with reference to FIG. 2, each of the zones 200 includes a plurality of ground select line structures GSL. For instance, in this embodiment, the ground select line structure GSL includes a first ground select line structure GSL1, a second ground select line structure GSL2, and a third ground select line structure GSL3, wherein the second ground select line structure GSL2 is disposed between the first ground select line structure GSL1 and the third ground select line structure GSL3. The first ground select line structure GSL1, the second ground select line structure GSL2, and the third ground select line structure GSL3 may be respectively isolated by ground select line cut GLC. The ground select line structure GSL extends from a first end 200a of the zone 200 to a second end 200b of the zone 200. Each of the zones 200 further includes a central connection configuration CC. The central connection configuration CC is disposed between the first memory array configuration 206 and the second memory array configuration 208. The central connection configuration CC includes a first connect structure C1, a second connect structure C2, and a bridge structure BS. The first connect structure C1 is disposed along the first slit 202 to connect the first memory array configuration 206. The second connect structure C2 is disposed along the second slit 204 to connect the second memory array configuration 208. The bridge structure BS connects the first connect structure C1 and the second connect structure C2. The positional relationship between the first connect structure C1, the second connect structure C2, and bridge structure BS is similar to that in the previous embodiment, and thus it is not repeated herein. The zone 200 further includes string selection line cuts SLC, which may be disposed in the upper portion of the stack structure (such as the stack structure 100 in FIG. 3) to separate the upper layers of conductive layers in the stack structure. The string selection line cuts SLC are composed of insulating material, for example, silicon oxide. Consequently, two string selection lines SSL are accompanied by one ground select line structure GSL separated by ground select line cuts GLC. This design enables control of different sub-zones through the string selection lines SSL and prevents word line read interference.

For example, as shown in FIG. 3, the string selection line SSL and the ground select line structure GSL3 are electrically coupled to opposite ends of the vertical channel VC. The string selection line SSL is electrically connected between the bit line BL and the underlying word line WL, with the intersection of the string selection line SSL and the vertical channel VC defining a string select transistor. The third ground select line structure GSL3 is electrically connected between the source line plate SLP and the vertical channel VC, with the intersection of the third ground select line structure GSL3 and word line WL defining a ground select transistor. During a read operation of the memory device illustrated in FIG. 3, such as reading a selected memory cell in the first memory array configuration 206, a voltage is applied to the string selection line SSL electrically connected to the selected memory cell to activate the string select transistor electrically connected to the string selection line SSL. Simultaneously, a voltage is applied to the third ground select line structure GSL3 electrically connected to the selected memory cell to activate the ground select transistor electrically connected to the third ground select line structure GSL3. Due to the design in FIG. 2 where two string selection line SSLs are accompanied with one ground select line structure GSL, during this read operation, unselected memory cells remain deactivated, preventing capacitance generation in the channel layer 310 electrically connected to these unselected memory cells. This design mitigates issues such as increased word line load and read disturbance. In an embodiment, the channel layer 310 in unselected memory cells may be in an electrically floating state.

In FIG. 3, the third ground select line structure GSL3 is disposed at the lower portion of the stack structure 100, with the second connect structure C2 and a portion of the bridge structure BS located thereabove. In other words, the stack structure 100 of the central connection configuration CC includes the second connect structure C2 and the bridge structure BS. The word lines WL of the second memory array configuration 208 are the same layers as the conductive layers 104 of the second connect structure C2 and the bridge structure BS. Consequently, the second connect structure C2 directly connects to the second memory array configuration 208, and the bridge structure BS directly connects to the second memory array configuration 208 through the second connect structure C2. The second connect structure C2 is disposed directly above the third ground select line structure GSL3.

In FIG. 4, the first ground select line structure GSL1 is disposed at the lower portion of the stack structure 100, with the first connect structure C1 and a portion of the bridge structure BS located thereabove. In other words, the stack structure 100 in the central connection configuration CC includes the first connect structure C1 and the bridge structure BS. The word lines WL of the first memory array configuration 206 are the same layers as the conductive layers 104 of the first connect structure C1 and the bridge structure BS. Therefore, the first connect structure C1 directly connects to the first memory array configuration 206, and the bridge structure BS directly connects to the first memory array configuration 206 through the first connect structure C1. The first connect structure C1 is disposed directly above the first ground select line structure GSL1.

Referring to FIG. 2 and FIG. 5, the first ground select line structure GSL1, the second ground select line structure GSL2, and the third ground select line structure GSL3 are located in the lower portion LP of the stack structure 100. Moreover, the number of layers in the first ground select line structure GSL1, the second ground select line structure GSL2, and the third ground select line structure GSL3 may be increased or decreased as needed, and is not limited to the three layers shown in the FIG. 5. There are ground select line cuts GLC between the ground select line structures GSL, wherein the ground select line cuts GLC are composed of insulating materials, such as silicon oxide, SiN, SiON, SiC, SiCN, Al₂O₃, or high-k dielectric materials like HfO. Additionally, the ground select line cuts GLC may also be used to cut dummy word lines (not shown). Each of the zones 200 is disposed between the first slit 202 and the second slit 204 opposite to each other, and a discontinuous slit 210 may be placed between the first slit 202 and the second slit 204. The discontinuous slit 210 also extends from the first end 200a of the zone 200 to the second end 200b of the zone 200, and has at least one slit opening SO, for example, one or more. The bridge structure BS may be through the slit opening SO to achieve electrical connectivity, thus the bridge structure BS may pass through the slit openings SO directly above the second ground select line structure GSL2 and connect the first connect structure C1 and the second connect structure C2. In some embodiments, the first slit 202, the second slit 204, and the discontinuous slit 210 are all composed of insulating materials, such as silicon oxide. In other embodiments, the first slit 202, the second slit 204, and the discontinuous slit 210, in addition to the insulating materials, also include conductive materials encapsulated by the insulating materials, such as polysilicon or tungsten.

In FIG. 2, the memory device further includes a plurality of staircase parts SC located within the central connection configuration CC for each of the ground select line structures GSL. A plurality of ground select line contacts GC may be arranged to land on the staircase parts SC, respectively electrically connecting the plurality of ground select line structures GSL. In this embodiment, the staircase parts SC are separated from each other in the first direction D1, and the first direction D1 is the extension direction of the first slit 202.

In FIG. 3, the third ground select line structure GSL3 extending from one end of the second connect structure C2 relative to the second memory array configuration 208 has two separate staircase parts SC. The ground select line contacts GC land on the staircase parts SC respectively, to electrically connect a plurality of third ground select line structures GSL3 of the second memory array configuration 208 and a plurality of third ground select line structures GSL3 of the first memory array configuration 206 separately. Moreover, a dielectric layer 103 may be formed above the stack structure 100 to cover the staircase parts SC. The dielectric layer 103 may be single-layered or multi-layered. In some embodiments, the dielectric layer 103 includes silicon oxide, silicon nitride, silicon oxynitride, or a combination thereof.

In FIG. 4, the first ground select line structure GSL1, which extends from one end of the first connect structure C1 relative to the first memory array configuration 206, also includes two separate staircase parts SC. The ground select line contacts GC respectively land on the staircase parts SC, thereby electrically connecting a plurality of first ground select line structures GSL1 of the first memory array configuration 206 and a plurality of first ground select line structures GSL1 of the second memory array configuration 208, respectively.

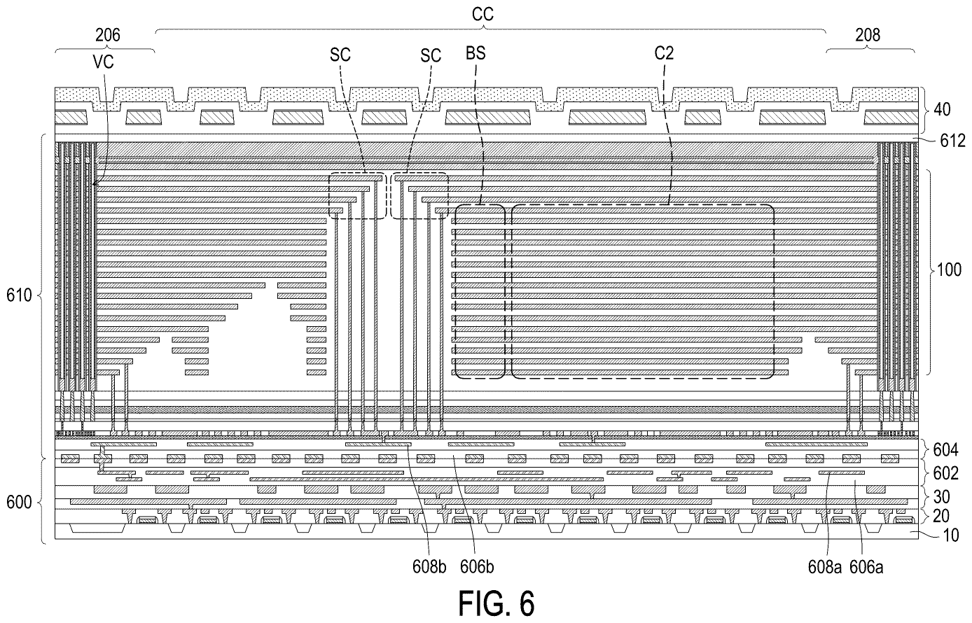

In addition to the CUA structure, the present disclosure may also be applied to a CBA (CMOS directly bonded to array) structure, as illustrated in FIG. 6. In FIG. 6, identical component symbols to those used in FIG. 3 are employed to represent identical or analogous parts and elements. The relevant content pertaining to these identical or analogous parts and elements may be referenced from the preceding embodiment and shall not be reiterated herein.

Referring to FIG. 6, a CMOS chip 600 includes a substrate 10, a device layer 20, and a metal interconnect structure 30. A redistribution layer 602 is formed on the metal interconnect structure 30, wherein the redistribution layer 602 includes a plurality of dielectric layers 606a and a plurality of conductive layers 608a. The stack structure 100 is formed in an array chip 610, as detailed in FIG. 3. In this figure, the stack structure 100 is an inverted version of the structure in FIG. 3, with the staircase parts SC disposed at the top, and the second connect structure C2 and the bridge structure BS located beneath the staircase parts SC. The array chip 610 further includes another redistribution layer 604 that interfaces with the CMOS chip 600, wherein the redistribution layer 604 includes a plurality of dielectric layers 606b and a plurality of conductive layers 608b. The CMOS chip 600 may be directly bonded to the array chip 610 through hybrid bonding between the redistribution layer 602 and the redistribution layer 604. Furthermore, a metal interconnect structure 40 may be formed on the backside of a substrate 612 of the array chip 610 to construct a CBA structure.

In light of the foregoing, an embodiment of the present disclosure discloses a memory device that is capable of connecting word lines of the first and second memory array configurations at two ends through identical or similar conductive paths, thereby reducing the word lines RC delay in the memory array structure.

What is claimed is:

1. A memory device, comprising a first memory array configuration, a second memory array configuration, and a central connection configuration located between the first memory array configuration and the second memory array configuration, the memory device comprising:
a stack structure comprising a plurality of insulating layers and a plurality of conductive layers stacked alternately in the first memory array configuration, the second memory array configuration, and the central connection configuration, wherein
a plurality of ground select line structures are included in the plurality of conductive layers in a lower portion of the stack structure in the first memory array configuration, the second memory array configuration, and the central connection configuration,
wherein the stack structure in the central connection configuration further comprises:
a first connect structure, connected with the stack structure of the first memory array configuration;
a second connect structure, connected with the stack structure of the second memory array configuration, wherein the second connect structure and the first connect structure are arranged in a staggered pattern; and
a bridge structure, connecting the first connect structure and the second connect structure.

2. The memory device of claim 1, wherein the first connect structure extends in a first direction, continuously extending from the first memory array configuration to the bridge structure, and the second connect structure extends in the first direction, continuously extending from the second memory array configuration to the bridge structure.

3. The memory device of claim 2, wherein the bridge structure extends in a second direction, and the second direction is different from the first direction.

4. The memory device of claim 2, further comprising a plurality of staircase parts in the central connection configuration for each of the plurality of ground select line structures, the plurality of staircase parts extending in the first direction.

5. The memory device of claim 4, wherein the plurality of staircase parts are separated from each other in the first direction.

6. The memory device of claim 4, further comprising a plurality of ground select line contacts, landing on the plurality of staircase parts, to electrically connect the plurality of ground select line structures respectively.

7. The memory device of claim 1, wherein the plurality of ground select line structures comprise a first ground select line structure, a second ground select line structure and a third ground select line structure, wherein the second ground select line structure is located between the first ground select line structure and the third ground select line structure.

8. The memory device of claim 7, wherein the first connect structure is disposed directly above the first ground select line structure, and the second connect structure is disposed directly above the third ground select line structure.

9. The memory device of claim 7, further comprising a plurality of staircase parts disposed in the first ground select line structure at an end of the first connect structure opposite to the first memory array configuration.

10. The memory device of claim 7, wherein the bridge structure is disposed directly above the second ground select line structure.

11. A memory device, comprising a plurality of zones, each of the zones is disposed between a first slit and a second slit opposite to each other for separating from adjacent zones of the plurality of zones, the memory device comprising:
a stack structure comprising a plurality of insulating layers and a plurality of conductive layers stacked alternately in each of the zones, wherein
the stack structure at a first end of the zone comprises a first memory array configuration;
the stack structure at a second end of the zone comprises a second memory array configuration; and
a plurality of ground select line structures included in a lower portion of the stack structure, the plurality of ground select line structures extending from the first end of the zone to the second end of the zone,
wherein each of the zones further comprises a central connection configuration between the first memory array configuration and the second memory array configuration, wherein the stack structure in the central connection configuration comprises:
a first connect structure, disposed along the first slit to connect the first memory array configuration;
a second connect structure, disposed along the second slit to connect the second memory array configuration; and
a bridge structure, connecting the first connect structure and the second connect structure.

12. The memory device of claim 11, further comprising a discontinuous slit disposed between the first slit and the second slit, and the discontinuous slit extends from the first end of the zone to the second end of the zone.

13. The memory device of claim 12, wherein the discontinuous slit has at least one slit opening, and the bridge structure is through the at least one slit opening.

14. The memory device of claim 11, further comprising a plurality of staircase parts in the central connection configuration for each of the plurality of ground select line structures.

15. The memory device of claim 14, wherein the plurality of staircase parts are separated from each other in a first direction, and the first direction is an extending direction of the first slit.

16. The memory device of claim 14, further comprising a plurality of ground select line contacts, landing on the plurality of staircase parts, to electrically connect the plurality of ground select line structures respectively.

17. The memory device of claim 11, wherein the plurality of ground select line structures comprise a first ground select line structure, a second ground select line structure and a third ground select line structure, wherein the second ground select line structure is located between the first ground select line structure and the third ground select line structure.

18. The memory device of claim 17, wherein the first connect structure is disposed directly above the first ground select line structure, and the second connect structure is disposed directly above the third ground select line structure.

19. The memory device of claim 17, further comprising a plurality of staircase parts disposed in the first ground select line structure at an end of the first connect structure opposite to the first memory array configuration.

20. The memory device of claim 17, wherein the bridge structure is disposed directly above the second ground select line structure.
